(19) United States
(12) Patent Application Publication
(10) Pub. No.: US 2015/0007882 A1
(43) Pub. Date: Jan. 8, 2015

(54) FLEXIBLE NANOWIRE BASED SOLAR CELL

(71) Applicant: KONINKLIJKIE PHILIPS N.V., EINDHOVEN (NL)

(72) Inventors: Luzia Silke Diedenhofen, Eindhoven (NL); Dirk Kornelis Gerhardus De Boer, Eindhoven (NL)

(73) Assignee: Koninklijke Philips N.V. a corporation

(21) Appl. No.: 14/376,869

(22) PCT Filed: Feb. 4, 2013
(86) PCT No.: PCT/IB2013/050943

§ 371 Date: Aug. 6, 2014

Related U.S. Application Data
(60) Provisional application No. 61/595,728, filed on Feb. 7, 2012.

(51) Int. Cl. H01L 31/0352; H01L 31/0224

(52) U.S. Cl. CPC H01L 31/035227; H01L 31/022466; H01L 31/022441
USPC 136/256

(57) ABSTRACT

A solar cell comprises a layer (12) of p/n-doped semiconductor nanowires (22), at least one polymer layer (10), wherein the layer (12) of p/n-doped semiconductor nanowires (22) is at least partially embedded in the polymer layer (10), and the polymer layer (10) has a first surface (32) and a second surface (34), wherein, in a state of operation, the first surface (32) is closer to incident light (20) at a location of incidence than the second surface (34), and wherein an area of the first surface (32) is larger than an area of the second surface (34).

### FIELD OF THE INVENTION

The invention pertains to a solar cell comprising semiconductor nanowires.

### BACKGROUND OF THE INVENTION

In the field of photovoltaic or solar cells it has been proposed to use p/n-doped semiconductor nanowires that are embedded in a polymer dielectric material. Semiconductor nanowires are grown standardly by chemical vapor deposition techniques, such as metal-organic vapor phase epitaxy (MOVPE) or molecular beam epitaxy (MBE) on crystalline substrates for epitaxial growth. Usually, the growth of the nanowires is catalyzed by a metal catalyst particle that defines the diameter of the nanowires. The metal catalyst particle can either be structured by nano-imprint techniques like substrate-conformal imprint lithography (SCIL), if order is required, or by depositing a thin film of gold on the substrate. Using this technique, the growth of radial and axial pn-junctions has been demonstrated, as well as hetero-epitaxial growth. Nanowires grow preferentially in the <111> crystallographic direction, so that nanowires grown on (111) substrates are vertically aligned. The as-grown, vertically aligned nanowires can be embedded in the polymer that allows wiping the nanowires from the substrate and allows reusing the substrate for another growth run. A semiconductor nanowire photovoltaic device of this kind has been described, for instance, in document US 2011/0240099 A1.

It is desirable to provide a solar cell using semiconductor nanowires which shows a flexible structure and an improved efficiency.

### SUMMARY OF THE INVENTION

It is therefore an object of the invention to provide a semiconductor nanowire-based solar cell that is mechanically stable, flexible and also shows an improved efficiency for converting incident light.

In one aspect of the present invention, the object is achieved by a solar cell, comprising a layer of p/n-doped semiconductor nanowires and at least one polymer layer, wherein the layer of p/n-doped semiconductor nanowires is at least partially embedded in the polymer layer. The polymer layer has a first surface and a second surface, wherein, in a state of operation, the first surface is closer to incident light at a location of incidence than the second surface. Further, an area of the first surface is larger than an area of the second surface. The phrase “area of a surface”, as used in this application, shall be understood particularly as the gross overall area that is parallel to the surface and that is bordered by the same borderline; meaning, in particular, that a portion of the surface area that is occupied by any object sticking out of the surface area shall not be subtracted from it.

The invention is based on the concept that with the area of the first surface being larger than the area of the second surface, a volumetric density of the semiconductor nanowires is lower in proximity to the first surface than in proximity to the second surface.

The effect of this is two-fold. For one, an effective refractive index of a compound layer, consisting of the polymer layer and the at least partially embedded layer of p/n-doped semiconductor nanowires is also varied such that it will be lowest in proximity to the first surface, matching a refractive index of air. This will allow for an almost perfect coupling of the incident light into the compound layer, as a reflected portion of the incident light is proportional to the square of a difference of the refractive index of air and the effective refractive index of the compound layer in proximity to an air/layer interface. In an adapted embodiment, a substantial improvement of a coupling of the incident light into the compound layer without any use of an anti-reflection (AR) coating may be accomplished.

Secondly, with the area of the first surface being larger than the area of the second surface, the volumetric density of the semiconductor nanowires is higher in proximity to the second surface than in proximity to the first surface. This results in a higher density of absorber medium in the proximity to the second layer, allowing for a maximum absorption there.

Moreover, due to the selection of materials, the resulting solar cell is lightweight and cost-efficient. The inherent flexibility of their structure renders the solar cells of the invention excellent for being mounted around a street lamp post or other electronically controlled signs e.g. speed signs on highways or the like.

In another aspect of the present invention, at least a portion of the first surface is curved in at least one direction. By that, a larger area of the first surface can be readily accomplished. In one embodiment, the portion of the first surface may be curved like a circular cylinder, wherein the direction the first surface is curved in is an azimuthal direction about a center axis of the cylinder. In yet another embodiment, the portion of the first surface may be curved in two directions that intersect or, in particular, are perpendicular to each other, resulting in the first surface having a shape of a spherical cap or, more generic, a portion of an ellipsoidal surface.

In a further aspect of the invention, an upper portion of the pn-doped semiconductor nanowires sticks out from the first surface of the polymer layer, thus providing easy access for electrically connecting to the upper portion of the semiconductor nanowires.

A monotonous increase of the effective refractive index of the compound layer in a direction from the first surface to the second surface can be obtained by aligning a majority of the pn-doped semiconductor nanowires in a direction that is essentially perpendicular to the first surface. The phrase “essentially perpendicular”, as used in this application, shall be understood particularly such that an orientation of the nanowires can differ from being perpendicular to the first surface by an angle of up to 30°, preferably up to 20°, and, more preferably, up to 10°. In the absence of boundaries in terms of refractive index, which are the cause for reflection of light incident to the boundary, any reflection of the incident light may be avoided, meaning that almost all of the incident light will be trapped inside the solar cell. Preferably, the p/n-doped semiconductor nanowires have a length in the micrometer range.

In a preferred embodiment, the layer of pn-doped semiconductor nanowires has a periodic structure in at least one direction. The phrase “periodic structure”, as used in this application, shall be understood particularly as a structure in which a certain feature thereof is repeated in regular distances in at least one direction. The repeated feature may include a combination of several features of the structure. The distances lie preferably within a range between 100 nm and 1500 nm. Homogeneous conditions of refraction for the incident light may be achievable thereby.

In another aspect of the invention, the first surface and the second surface of the polymer layer are essentially aligned in parallel. The phrase “essentially aligned”, as used in this application, shall be understood particularly such that deviations from a perfect alignment shall be smaller than 20%, preferably smaller than 10% of an average distance between the first surface and the second surface. This may allow for an easy realization of the area of the first surface being larger than the area of the second surface, starting from a plate-like polymer layer with embedded semiconductor nanowires, by a simple bending process.

In another aspect of the invention, the solar cell further comprises a top layer made from a transparent conducting oxide (TCO), wherein the top layer has an upper third surface that, in the state of operation, is closer to the incident light at the location of incidence than the first surface. Thereby, in an adapted embodiment a transparent electrical connection to the pn-doped semiconductor nanowires may be accomplished, and also with a curved first surface. Preferably, the electrical connections that are provided between the top layer and the semiconductor nanowires are ohmic contacts.

Preferably, the solar cell may further comprise a bottom layer formed by metal, wherein the bottom layer contacts a majority of the p/n-doped semiconductor nanowires as well as the second surface of the polymer layer. Thus, an easy realization of an electrical connection to the pn-doped semiconductor nanowires in proximity to the second surface may be accomplished, as well a reflection of incident light by a preferably shiny metal surface that is facing the semiconductor nanowires, as an optical path length for the incident light is increased by reflecting the light that is not absorbed during the first transit through the layer at the shiny metal surface.

### BRIEF DESCRIPTION OF THE DRAWINGS

These and other aspects of the invention will be apparent from and elucidated with reference to the embodiments described hereinafter. Such embodiment does not necessarily represent the full scope of the invention, however, and reference is made therefore to the claims and herein for interpreting the scope of the invention.

In the drawings:

FIG. 1 illustrates a layer of semiconductor nanowires in a plan view and in a slanted top view,

FIG. 2 shows a schematic cross-sectional view of a compound layer of a polymer and the semiconductor nanowires of FIG. 1 in an intermediate step of production,

FIG. 3 shows a schematic cross-sectional view of a compound layer of a polymer layer and the semiconductor nanowires of FIG. 1 in a later step of production, and

FIG. 4 is a diagram illustrating a functional dependency of an effective refractive index of the compound layer of FIG. 2 from a distance to an air/compound layer boundary.

### DETAILED DESCRIPTION OF EMBODIMENTS

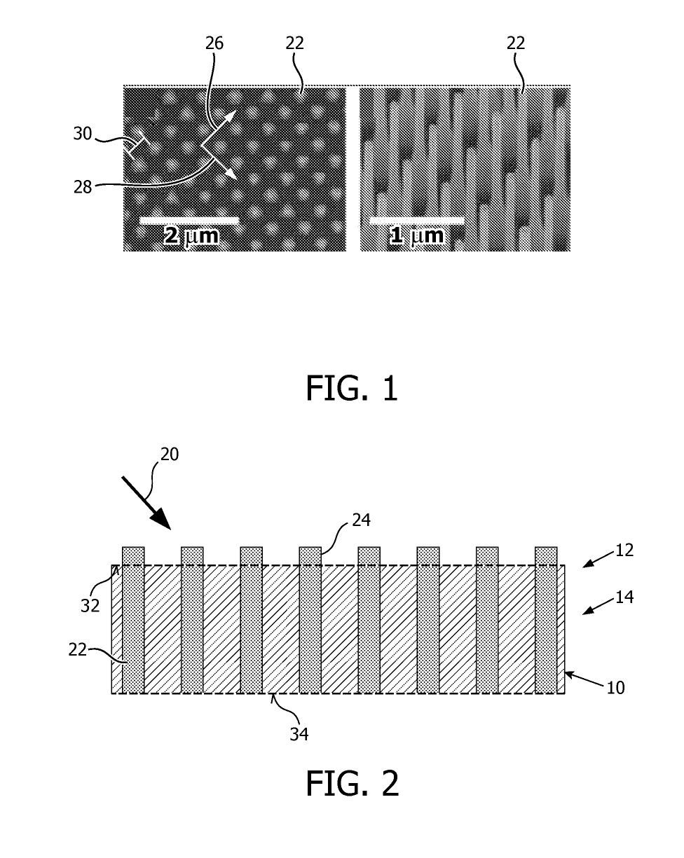

FIG. 1 shows a layer 12 of semiconductor nanowires 22 that has a periodic structure in two directions 26, 28 that lie in a plane of the layer 12 and that are arranged perpendicular to each other. A pitch 30 of the periodic structure is about 515 nm in both directions 26, 28.

The semiconductor nanowires 22 were grown by metal-organic vapor phase epitaxy on a (111) semiconductor substrate and are aligned perpendicular to a plane of the substrate, having an average length of about 3 μm. Each of the semiconductor nanowires 22 exhibits an axial pn-junction. After growth, a polymer layer 10 is applied by spin-coating onto the semiconductor nanowires 22. The polymer layer 10 has a first surface 32 and a second surface 34, both of which are aligned in parallel to the plane of the semiconductor substrate, as illustrated in the cross-sectional view of FIG. 2. The first surface 32 and the second surface 34 are indicated by dashed lines. A majority of the pn-doped semiconductor nanowires 22 is therefore aligned in a direction 38 that is perpendicular to the first surface 32.

The polymer layer 10 and the layer 12 of p/n-doped semiconductor nanowires 22 form a compound layer 14 such that the layer 12 of p/n-doped semiconductor nanowires 22 is partially embedded in the polymer layer 10, and an upper portion 24 of the pn-doped semiconductor nanowires 22 sticks out from the first surface 32 of the polymer layer 10. In a next step, the compound layer 14 is mechanically removed from the underlying semiconductor substrate using a razor blade. FIG. 2 shows the compound layer after removal of the semiconductor substrate which is re-usable after cleaning, whereby production costs are lowered.

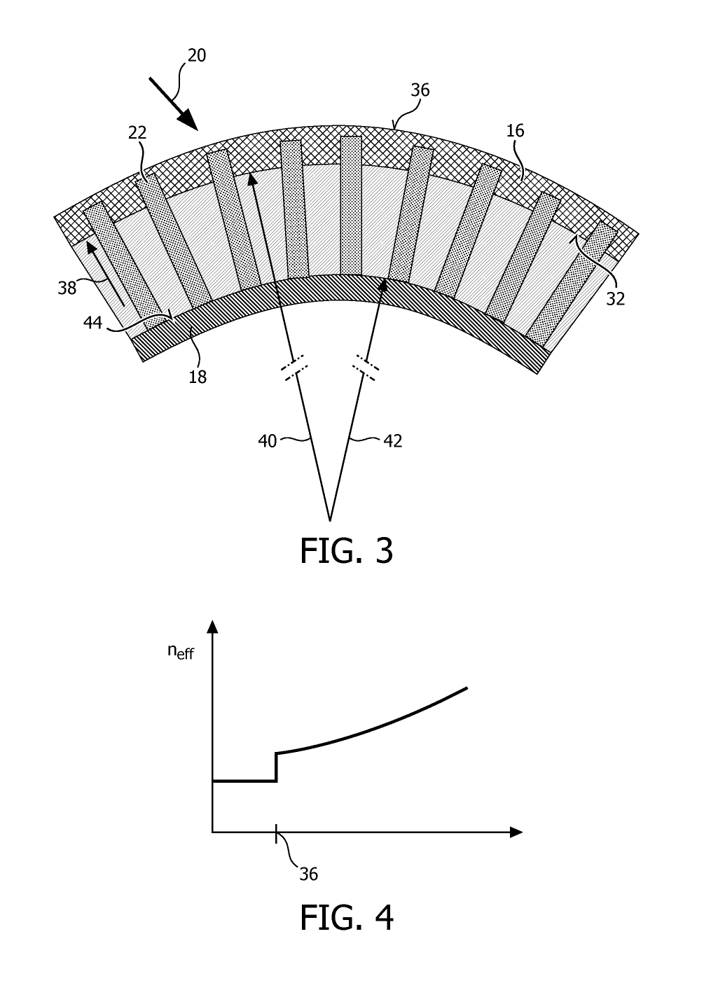

The compound layer 14 is then bent such that the complete first surface 32 is curved to build a shape of a portion of a circular cylinder surface with a first radius 40 (FIG. 3). The first surface 32 and the second surface 34 remain aligned in parallel to each other so that the second surface 34 also has the shape of another circular cylinder surface of a second, smaller radius 42. Thus, by the bending process, an area of the first surface 32 is obviously larger than an area of the second surface 34.

As a result of the bending, an average volumetric density of the semiconductor nanowires 22 which is to be taken over volumes of cubes with a side length that is larger than the pitch 30 of the periodic structure is lower in proximity to the first surface 32, than in proximity to the second surface 34. An effective refractive index n_{eff} of the compound layer 14 is thus also varied such that it will be lowest in proximity to the first surface 32 and highest in proximity to the second surface 34 (FIG. 4). The bending of the compound layer 14 is carried out such that a desired dependency of the effective refractive index n_{eff} on a distance to the first surface 32 is achieved. After completion, the solar cell is meant to be arranged such that incident light 20 will pass the first surface 32 before it reaches the second surface 34.

In a further production step of the solar cell, a metal bottom layer 18 is evaporated or sputtered onto the second surface 34 (FIG. 3). The metal bottom layer 18 contacts the p/n-doped semiconductor nanowires 22 as well as the second surface 34 of the polymer layer 10. The metal is selected such that its work function provides an ohmic contact with the p/n-doped semiconductor nanowires 22 in proximity to the second surface 34. The metal bottom layer 18 has a shiny surface 44 facing the second surface 34 of the polymer layer 10, so that the solar cell is furnished with a light reflector, and the incident light 20 that has not been absorbed during a first path from the first surface 32 to the bottom layer 18 cannot escape the structure and will still be absorbed, thus improving a conversion efficieny of the solar cell.

In yet another step of production of the solar cell, a top layer 16 is formed by evaporation or sputtering of a transparent conducting oxide (TCO) on top of the compound layer 14. The top layer 16 forms an upper third surface 36 (FIG. 3). Moreover, the top layer 16 builds ohmic contacts with the p/n-doped semiconductor nanowires 22.

FIG. 3 shows the solar cell in a ready-for-operation state. The first surface 32 is closer to the incident light 20 at a location of incidence than the second surface 34, and the third surface 36 is closer to the incident light 20 at the location of incidence than the first surface 32. As shown in FIG. 4, the refractive index n_{eff} of the compound layer 14 of the solar cell rises step-like at the third surface 36 forming a boundary between the air and the transparent conducting oxide (TCO) layer, and is slowly increasing with distance from the first surface 32 due to the increasing volumetric density of the semiconductor nanowires 22.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

### REFERENCE SYMBOL LIST

10 polymer layer

12 layer of semiconductor nanowires

14 compound layer

16 top layer

18 bottom layer

20 incident light

22 semiconductor nanowire

24 upper portion

26 direction

28 direction

30 pitch

32 first surface

34 second surface

36 third surface

38 direction

40 radius 1^{st}

42 radius 2^{nd}

44 shiny surface

n_{eff} effective refractive index

1. A solar cell, comprising:
a layer of p/n-doped semiconductor nanowires,
at least one polymer layer, wherein the layer of p/n-doped semiconductor nanowires is partially embedded in the polymer layer, and
the polymer layer has a first surface and a second surface, wherein, in a state of operation, the first surface is closer to incident light at a location of incidence than the second surface, wherein an upper portion of the pn-doped semiconductor nanowires sticks out from the first surface of the polymer layer, and wherein
an area of the first surface is larger than an area of the second surface.

2. The solar cell as claimed in claim 1, wherein at least a portion of the first surface is curved in at least one direction.

3. (canceled)

4. The solar cell as claimed in claim 1, wherein a majority of the pn-doped semiconductor nanowires is aligned in a direction that is essentially perpendicular to the first surface.

5. The solar cell as claimed in claim 1, wherein the layer of pn-doped semiconductor nanowires has a periodic structure in at least one direction.

6. The solar cell as claimed in claim 1, wherein the first surface and the second surface of the polymer layer are essentially aligned in parallel.

7. The solar cell as claimed in claim 1, further comprising a top layer made from a transparent conducting oxide, wherein the top layer has an upper third surface that, in the state of operation, is closer to the incident light at the location of incidence than the first surface.

8. The solar cell as claimed in claim 1, further comprising a bottom layer formed by metal, wherein the bottom layer contacts a majority of the p/n-doped semiconductor nanowires as well as the second surface of the polymer layer.
